(19) United States
(12) Patent Application Publication
(10) Pub. No.: US 2023/0315962 A1
(43) Pub. Date: Oct. 5, 2023

(54) COVER UNIT DETERMINING METHOD, APPARATUS, AND DEVICE, AND STORAGE MEDIUM

(71) Applicant: SANECHIPS TECHNOLOGY CO., LTD., Shenzhen (CN)

(72) Inventors: Xiaoming SI, Shenzhen (CN); Tianlong FAN, Shenzhen (CN)

(21) Appl. No.: 18/012,545

(22) PCT Filed: Jun. 18, 2021
(86) PCT No.: PCT/CN2021/100849

§ 371 Date: Dec. 22, 2022

(30) Foreign Application Priority Data
Jun. 22, 2020 (CN) 202010576340.4

(51) Int. Cl. G06F 30/367

(52) U.S. Cl. CPC G06F 30/367

(57) ABSTRACT

Provided are a shelter unit determining method and apparatus, a device, and a storage medium. The method includes: simulating a high frequency circuit model through simulation software to obtain a simulation result; and determining a size of a shelter unit in a high frequency circuit according to the simulation result and a phase stability indication. In this manner, a shelter unit can be designed in an actual circuit based on a determined size, thereby implementing capacitance compensation without increasing the power consumption of a system.

### CROSS-REFERENCES TO RELATED APPLICATIONS

This disclosure claims priority to Chinese Patent Application No. 202010576340.4 filed with the China National Intellectual Property Administration (CNIPA) on Jun. 22, 2020 and titled “SHELTER UNIT DETERMINING METHOD AND APPARATUS, DEVICE, AND STORAGE MEDIUM”, the disclosure of which is incorporated herein by reference in its entirety.

### TECHNICAL FIELD

Embodiments of the present disclosure relate to the field of signal phase compensation and, in particular, to a shelter unit determining method and apparatus, a device, and a storage medium.

### BACKGROUND

In a conventional transmitter, a transmission module is generally divided into multiple transmission units. As shown in FIG. 1, the transmit power is adjusted by controlling the on and off of the transmission unit to achieve the attenuator (ATT) function of the transmitter. However, in the processes of turning on and turning off the transmission unit, the load during the processing of an intermediate frequency signal changes, causing fluctuations in the phase of the intermediate frequency signal.

At present, one solution to the preceding problem is: the turn-on and turn-off of the transmission unit are set at an output end, the signal is shorted to a power supply to achieve the ATT function of the signal power, and the connected load remains unchanged when the transmission unit switches between the on state and the off state to keep the phase of the intermediate frequency signal stable. Another solution is: an additional compensation unit is added to the output side of the transmission unit to compensate for the phase change of a modulated signal. However, the first manner described above is not advantageous for low-power consumption applications. The second manner compensates for the phase of the modulated signal after the radio frequency and the intermediate frequency are mixed and is not advantageous for multi-scenario applications.

### SUMMARY

The main object of the embodiments of the present disclosure is to provide a shelter unit determining method and apparatus, a device, and a storage medium to design a shelter unit in an actual circuit based on a determined size, thereby implementing capacitance compensation without increasing power consumption of a system.

To achieve the preceding object, according to a first aspect, an embodiment of the present disclosure provides a shelter unit determining method. The method includes: a high frequency circuit model is simulated through simulation software to obtain a simulation result, and a size of a shelter unit is determined according to the simulation result and a phase stability indication, where the shelter unit is a circuit unit in the high frequency circuit model.

To achieve the preceding object, according to a second aspect, an embodiment of the present disclosure provides a shelter unit determining apparatus. The apparatus includes: a simulation module, which is configured to simulate a high frequency circuit model through simulation software to obtain a simulation result, and a determination module, which is configured to determine a size of a shelter unit according to the simulation result and a phase stability indication, where the shelter unit is a circuit unit in the high frequency circuit model.

To achieve the preceding object, according to a third aspect, an embodiment of the present disclosure provides a device. The device includes a memory, a processor, a program stored in the memory and executable by the processor, and a data bus configured to enable connection communication between the processor and the memory, where the program, when executed by the processor, performs steps of the preceding method.

To achieve the preceding object, according to a fourth aspect, an embodiment of the present application provides a read-write storage medium for computer storage, where the storage medium stores one or more programs, and the one or more programs are executable by one or more processors to perform steps of the preceding method.

The embodiments of the present disclosure provide a shelter unit determining method and apparatus, a device, and a storage medium. In the method, a high frequency circuit model is simulated through simulation software to obtain a simulation result, and the size of a shelter unit in a high frequency circuit is determined according to the simulation result and a phase stability indication. In this manner, a shelter unit can be designed in an actual circuit based on a determined size, thereby implementing capacitance compensation without increasing the power consumption of a system.

### BRIEF DESCRIPTION OF DRAWINGS

FIG. 1 is a schematic diagram of the implementation of the ATT function of a transmitter in the existing art.

FIG. 2 is a principle diagram of ATT phase compensation according to an embodiment of the present disclosure.

FIG. 3 is a flowchart of a shelter unit determining method according to an embodiment of the present disclosure.

FIG. 4 is a schematic diagram of a high frequency circuit model according to an embodiment of the present disclosure.

FIG. 5 is a flowchart of the determination of the size of a shelter unit according to a simulation result and a phase stability indication according to an embodiment of the present disclosure.

FIG. 6 is a flowchart of the determination of the size of a shelter unit according to a simulation result and a phase stability indication according to an embodiment of the present disclosure.

FIG. 7 is a structure diagram of a shelter unit determining apparatus according to an embodiment of the present disclosure.

FIG. 8 is a structure diagram of a device according to an embodiment of the present disclosure.

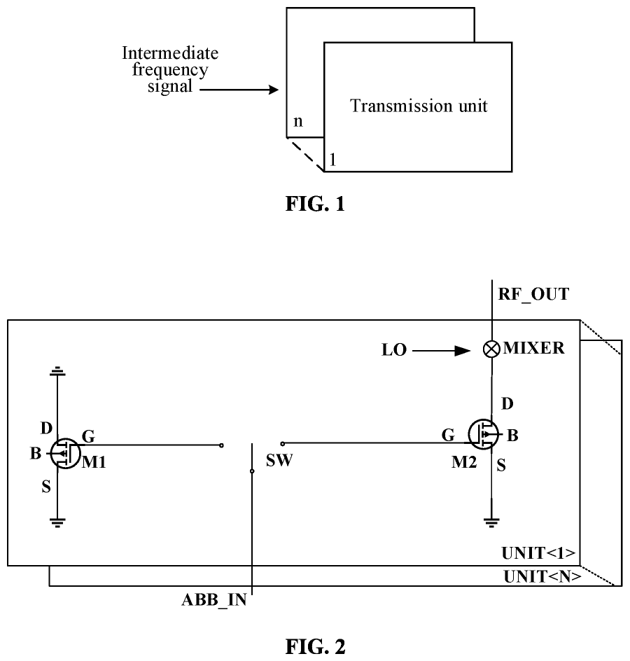

### DETAILED DESCRIPTION

Objects, solutions and advantages of the present disclosure will be more apparent from a detailed description of embodiments of the present disclosure in conjunction with the drawings. It is to be noted that if not in collision, the embodiments and features therein in the present disclosure may be combined with each other.

In addition, in the embodiments of the present disclosure, the word “optionally” or “exemplarily” is used herein to mean serving as an example, instance, or illustration. Any embodiment or design described herein as “optional” or “exemplary” is not necessarily to be construed as preferred or advantageous over other embodiments or designs. Rather, the use of the word “optionally” or “exemplarily” is intended to present related concepts in a concrete manner.

An embodiment of the present disclosure provides a shelter unit determining method. By setting a shelter unit, when the transmission units are switched to achieve the ATT function, the method may compensate for the change of an ABB output load through the shelter unit to keep the phase of the intermediate frequency signal stable. In multiple transmission units (UNIT<1> to UNIT<N>) shown in FIG. 2, each transmission unit includes a switch SW, a shelter unit (DUMMY transistor M1), a field-effect transistor M2 and a mixer MIXER. In FIG. 2, ABB IN is an intermediate frequency signal, L0 is a local oscillator signal, and RF OUT is an output signal of the transmission unit. For the transmission unit, the ATT function is achieved by controlling the on and off of the SW, and the load is kept unchanged under the ATT function when the SW switches to enable the intermediate frequency signal to access the M1.

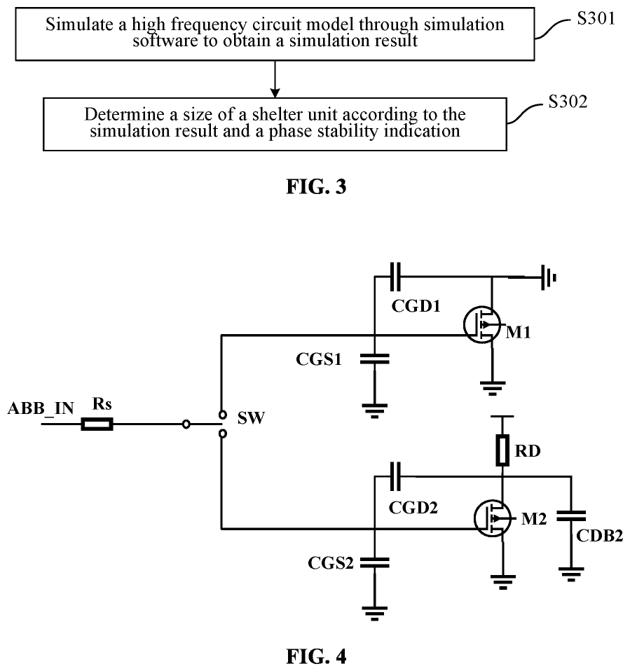

FIG. 3 is a flowchart of a shelter unit determining method according to an embodiment of the present disclosure. As shown in FIG. 3, the method includes S301 and S302.

In S301, a high frequency circuit model is simulated through simulation software to obtain a simulation result.

For example, the high frequency circuit model in S301 may be a circuit having a structure as shown in FIG. 4, and the circuit may include a switch SW, capacitors CGS1, CGD1, CGS2, CGD2 and CDB2, resistors Rs and RD, a shelter unit (DUMMY transistor) M1 and a field-effect transistor M2, where ABB IN is an input intermediate frequency signal.

The simulation software in S301 may be any software that can perform circuit simulation in the existing art and is not limited by the embodiments of the present disclosure. The high frequency circuit model shown in FIG. 4 is simulated through the simulation software to obtain a simulation result.

In S302, a size of a shelter unit is determined according to the simulation result and a phase stability indication.

In S302, the phase stability indication may be understood as relevant indication information about the stability of the phase of the intermediate frequency signal. After the high frequency circuit simulation result is obtained by software simulation, the size of the shelter unit in the high frequency circuit model may be determined based on the simulation result and the phase stability indication.

According to the method for determining the size of the shelter unit provided by the embodiments of the present disclosure, the high frequency circuit model is simulated through the simulation software to obtain a simulation result, and the size of the shelter unit in a high frequency circuit is determined according to the simulation result and the phase stability indication. In this manner, a shelter unit can be designed in an actual circuit based on a determined size, thereby implementing capacitance compensation without increasing the power consumption of a system.

In an embodiment, the phase stability indication in S302 includes a first input pole being same as a second input pole.

In this embodiment, the first input pole may be understood as an input pole when a switch turns on a field-effect transistor, and the second input pole may be understood as an input pole when the switch turns on the shelter unit. As shown in FIG. 4, when the switch SW turns on the M2, the transmission unit is turned on, and at this moment, the input pole is the first input pole denoted by win2; when the switch SW turns on the M1, the transmission unit is turned off, and at this moment, the input node is the second input pole denoted by win1. That is, the phase stability indication requires win2=win1.

In an embodiment, the first input pole win2 may be determined by a first formula, and the first formula is:

$${w}_{in 2} = \frac{1}{{R}_{s} * [ {C}_{GS 2} + ( 1 + {g}_{m 2} * {R}_{D} ) * {C}_{GD 2} ]} . \qquad ( 1 )$$

In the first formula, Rs and RD are resistors in the high frequency circuit model, CGS2 and CGD2 are capacitors in the high frequency circuit model, and gm2 is a transconductance coefficient.

The second input pole win1 may be determined by a second formula, and the second formula is:

$${w}_{in 1} = \frac{1}{{R}_{s} * [ {C}_{GS 1} + {C}_{GD 1} ]} . \qquad ( 2 )$$

In the second formula, Rs is a resistor in the high frequency circuit model, and CGS1 and CGD1 are capacitors in the high frequency circuit model.

That is, the phase stability indication requires that the parameters of each component in the high frequency circuit model satisfy the following formula:

$$\frac{1}{{C}_{GS 1} + {C}_{GD 1}} = \frac{1}{{C}_{GS 2} + ( 1 + {g}_{m 2} * {R}_{D} ) * {C}_{GD 2}} . \qquad ( 3 )$$

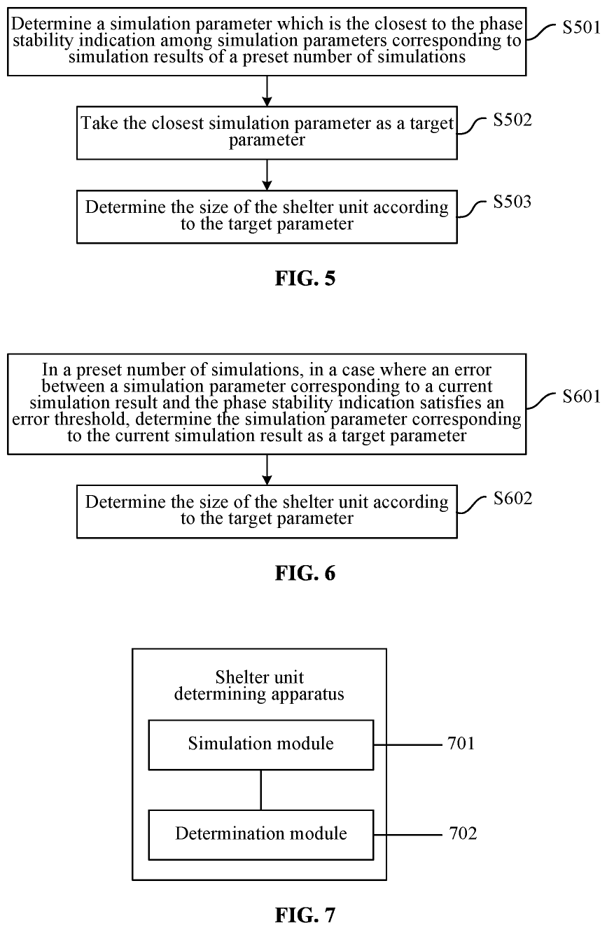

As shown in FIG. 5, in an embodiment, the specific implementation of determining the size of the shelter unit according to the simulation result and the phase stability indication in S302 may include, but is not limited to, steps S501 and S502.

In S501, a simulation parameter which is the closest to the phase stability indication among simulation parameters corresponding to simulation results of a preset number of simulations is determined.

In this embodiment, for example, it is assumed that the preset number of simulations is set to n, and n is an integer greater than or equal to 1. In the n simulation results, simulation parameters corresponding to the n simulation results exist. A simulation parameter which is the closest to the phase stability indication is determined according to the simulation parameters corresponding to the n simulation results.

Further, the simulation parameter which is the closest to the phase stabilization indication may be understood as component parameters in a simulation result whose values are the closest to the parameter values required by the phase stability indication.

In S502, the closest simulation parameter is taken as a target parameter.

In S503, the size of the shelter unit is determined according to the target parameter.

That is, a simulation parameter of a simulation result which is the closest to the phase stability indication among the simulation results of a preset number of simulations is determined based on the phase stability indication, and the size of the shelter unit is determined according to the simulation parameter.

As shown in FIG. 6, in an embodiment, the specific implementation of determining the size of the shelter unit according to the simulation result and the phase stability indication in S302 may include, but is not limited to, steps S601 and S602.

In S601, in a preset number of simulations, in a case where an error between a simulation parameter corresponding to a current simulation result and the phase stability indication satisfies an error threshold, the simulation parameter corresponding to the current simulation result is determined as a target parameter.

In this embodiment, for example, it is assumed that the preset number of simulations is set to m, and m is an integer greater than or equal to 2. In the simulation process, if the error between a simulation parameter corresponding to the simulation result of a k^{th} (k≤m) simulation and the phase stability indication satisfies the error threshold, the simulation parameter corresponding to the simulation result of the k^{th} simulation is determined as the target parameter.

In a case where k<m, the high frequency circuit model does not need to be simulated m times. If the error between the simulation parameter of the simulation result of the kth simulation and the phase stability indication satisfies the error threshold, the simulation parameter corresponding to the simulation result of the k^{th} simulation may be directly determined as the target parameter, and the subsequent simulation process may be terminated.

In S602, the size of the shelter unit is determined according to the target parameter.

The size of the shelter unit is determined according to the target parameter determined in the preceding steps, and thus shelter unit can be designed in an actual circuit based on a determined size, thereby implementing capacitance compensation without increasing the power consumption of a system.

Optionally, in this embodiment, the shelter unit designed based on the preceding size of the shelter unit may be divided into multiple sub-units to improve compensation accuracy.

Further, the shelter unit determining method provided by the embodiments of the present disclosure may further include: a component in each sub-unit is automatically detected and matched. For example, the parameters of the component in each sub-unit may be determined by a dichotomy or the like to achieve the type selection of the component.

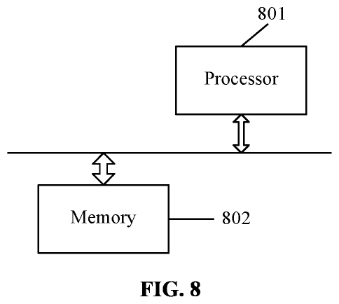

FIG. 7 is a structure diagram of a shelter unit determining apparatus according to an embodiment of the present disclosure. As shown in FIG. 7, the apparatus may include a simulation module 701 and a determination module 702.

The simulation module 701 is configured to simulate a high frequency circuit model through simulation software to obtain a simulation result.

The determination module 702 is configured to determine a size of a shelter unit according to the simulation result and a phase stability indication.

In this embodiment, the shelter unit is a circuit unit in the high frequency circuit model.

In an embodiment, the phase stability indication may include a first input pole being same as a second input pole.

The first input pole is an input pole when a switch turns on a field-effect transistor, the second input pole is an input pole when the switch turns on the shelter unit, and the switch and the field-effect transistor are circuit units in the high frequency circuit model.

For example, the first input pole may be marked as win2, win2 may be determined by a first formula, and the first formula is the preceding formula (1). Similarly, the second input pole may be marked as win1, win1 may be determined by a second formula, and the second formula is the preceding formula (2). The phase stability indication requires that the formula (1) is equal to formula (2), that is, the phase stability indication requires that the parameters of each component in the high frequency circuit model satisfy the preceding formula (3).

In an embodiment, the determination module may be configured to determine a simulation parameter which is the closest to the phase stability indication among simulation parameters corresponding to simulation results of a preset number of simulations; take the closest simulation parameter as a target parameter, and determine the size of the shelter unit according to the target parameter.

In an embodiment, the determination module may be configured to, in a preset number of simulations, determine, in a case where an error between a simulation parameter corresponding to a current simulation result and the phase stability indication satisfies an error threshold, the simulation parameter corresponding to the current simulation result as a target parameter, and determine the size of the shelter unit according to the target parameter.

Optionally, the apparatus may further include a matching module.

The method matching module is configured to, in a case where the shelter unit is multiple sub-units, automatically detect and match a component in each sub-unit.

The shelter unit determining apparatus provided by this embodiment is configured to perform the shelter unit determining method of the embodiment shown in FIG. 3. The implementation principles and technical effects of the shelter unit determining apparatus are similar to those of the shelter unit determining method, and the details are not repeated here.

FIG. 8 is a structure diagram of a device according to an embodiment of the present disclosure. As shown in FIG. 8, the device includes a processor 801 and a memory 802. The number of processors 801 in the device may be one or more (one processor 801 is used as an example in FIG. 8). The processor 801 and the memory 1102 in the device may be connected via a bus or in other ways (the connection via the bus is used as an example in FIG. 8).

As a computer-readable storage medium, the memory 802 may be configured to store software programs, computer-executable programs and modules, such as program instructions/modules (for example, the simulation module 701 and the determination module 702 in the shelter unit determining apparatus) corresponding to the shelter unit determining method of the embodiment shown in FIG. 3. The processor 801 runs the software programs, instructions and modules stored in the memory 802 to perform the preceding data modulation method.

The memory 802 may mainly include a program storage region and a data storage region, where the program storage region may store an operating system and an application program required by at least one function while the data storage region may store data created depending on the use of a set-top box. In addition, the memory 802 may include a high-speed random-access memory, and may also include a non-volatile memory such as at least one disk memory, flash memory or another non-volatile solid-state memory.

An embodiment of the present application further provides a read-write storage medium for computer storage, where the storage medium stores one or more programs, and the one or more programs are executable by one or more processors to perform a shelter unit determining method. The method includes the following.

A high frequency circuit model is simulated through simulation software to obtain a simulation result.

A size of a shelter unit is determined according to the simulation result and a phase stability indication.

The shelter unit is a circuit unit in the high frequency circuit model.

An embodiment of the present disclosure provides a computer program product, which includes a computer program stored in a non-transitory computer-readable storage medium. The computer program includes program instructions which, when executed by a computer, cause the computer to perform the method in any one of the method embodiments described above. It is to be understood by those skilled in the art that the embodiments of the present disclosure may be provided as methods, systems or computer program products. The present disclosure may adopt the form of a computer program product implemented on one or more computer-usable storage media (including, but not limited to, a disk memory and an optical memory, etc.) that include computer-usable program codes. It is to be understood by those of ordinary skill in the art that some or all steps in the preceding disclosed method and function modules/units in the device may be implemented as software, firmware, hardware and suitable combinations thereof.

In the hardware implementation, the division of the function modules/units mentioned in the above description may not correspond to the division of physical components. For example, one physical component may have several functions, or one function or step may be executed jointly by several physical components. Some or all physical components may be implemented as software executed by a processor such as a central processing unit, a digital signal processor or a microprocessor, may be implemented as hardware, or may be implemented as integrated circuits such as application-specific integrated circuits. Such software may be distributed on computer-readable media. The computer-readable media may include computer storage media (or non-transitory media) and communication media (or transitory media). As is well known to those of ordinary skill in the art, the term computer storage media include volatile and nonvolatile, removable and non-removable media implemented in any method or technology for storage of information (such as computer-readable instructions, data structures, computer program modules or other data). The computer storage media include, but are not limited to, random-access memories (RAMs), read-only memories (ROMs), electrically erasable programmable read-only memories (EEPROMs), flash memories or other memory technologies, compact disc read-only memories (CD-ROMs), digital versatile disks (DVDs) or other optical disk memories, magnetic cassettes, magnetic tapes, magnetic disk memories or other magnetic storage devices, or any other media used for storing desired information and accessed by a computer. Additionally, as known to those of ordinary skill in the art, the communication media generally include computer-readable instructions, data structures, program modules or other data in carriers or in modulated data signals transported in other transport mechanisms and may include any information delivery medium.

The preferred embodiments of the present disclosure are illustrated herein with reference to drawings and are not intended to limit the scope of the present disclosure. Any modifications, equivalent substitutions and improvements made by those skilled in the art without departing from the scope and spirit of the present disclosure shall fall within the scope of the claims of the present disclosure.

1. A shelter unit determining method, comprising:
simulating a high frequency circuit model through simulation software to obtain a simulation result; and
determining a size of a shelter unit according to the simulation result and a phase stability indication;
wherein the shelter unit is a circuit unit in the high frequency circuit model.

2. The method of claim 1, wherein the phase stability indication comprises a first input pole being same as a second input pole;
wherein the first input pole is an input pole when a switch turns on a field-effect transistor, the second input pole is an input pole when the switch turns on the shelter unit, and the switch and the field-effect transistor are circuit units in the high frequency circuit model.

3. The method of claim 2, wherein the first input pole is win2, and win2 is determined by a first formula, wherein the first formula is:
$${w}_{in 2} = \frac{1}{{R}_{s} * [ {C}_{GS 2} + ( 1 + {g}_{m 2} * {R}_{D} ) * {C}_{GD 2} ]} ,$$
wherein Rs and RD are resistors in the high frequency circuit model, CGS2 and CGD2 are capacitors in the high frequency circuit model, and gm2 is a transconductance coefficient.

4. The method of claim 2, wherein the second input pole is win1, and win1 is determined by a second formula, wherein the second formula is:
$${w}_{in 1} = \frac{1}{{R}_{s} * [ {C}_{GS 1} + {C}_{GD 1} ]} ,$$
wherein Rs is a resistor in the high frequency circuit model, and CGS1 and CGD1 are capacitors in the high frequency circuit model.

5. The method of claim 1, wherein determining the size of the shelter unit according to the simulation result and the phase stability indication comprises:
determining a simulation parameter which is the closest to the phase stability indication among simulation parameters corresponding to simulation results of a preset number of simulations;
taking the closest simulation parameter as a target parameter; and
determining the size of the shelter unit according to the target parameter.

6. The method of claim 1, wherein determining the size of the shelter unit according to the simulation result and the phase stability indication comprises:
in a preset number of simulations, determining, in a case where an error between a simulation parameter corresponding to a current simulation result and the phase stability indication satisfies an error threshold, the simulation parameter corresponding to the current simulation result as a target parameter; and
determining the size of the shelter unit according to the target parameter.

7. The method of claim 1, wherein in a case where the shelter unit is a plurality of sub-units, the method further comprises:
automatically detecting and matching a component in each of the plurality of sub-units.

8. (canceled)

9. A device, comprising a memory, a processor, a program stored in the memory and executable by the processor, and a data bus configured to enable connection communication between the processor and the memory, wherein the program, when executed by the processor, performs the following steps:
simulating a high frequency circuit model through simulation software to obtain a simulation result; and
determining a size of a shelter unit according to the simulation result and a phase stability indication;
wherein the shelter unit is a circuit unit in the high frequency circuit model.

10. A non-transitory read-write storage medium, which is used for computer storage, wherein the storage medium stores one or more programs, and the one or more programs are executable by one or more processors to perform the following steps:
simulating a high frequency circuit model through simulation software to obtain a simulation result and
determining a size of a shelter unit according to the simulation result and a phase stability indication;
wherein the shelter unit is a circuit unit in the high frequency circuit model.

11. The method of claim 2, wherein determining the size of the shelter unit according to the simulation result and the phase stability indication comprises:
determining a simulation parameter which is the closest to the phase stability indication among simulation parameters corresponding to simulation results of a preset number of simulations;
taking the closest simulation parameter as a target parameter; and
determining the size of the shelter unit according to the target parameter.

12. The method of claim 3, wherein determining the size of the shelter unit according to the simulation result and the phase stability indication comprises:
determining a simulation parameter which is the closest to the phase stability indication among simulation parameters corresponding to simulation results of a preset number of simulations;
taking the closest simulation parameter as a target parameter; and
determining the size of the shelter unit according to the target parameter.

13. The method of claim 4, wherein determining the size of the shelter unit according to the simulation result and the phase stability indication comprises:
determining a simulation parameter which is the closest to the phase stability indication among simulation parameters corresponding to simulation results of a preset number of simulations;
taking the closest simulation parameter as a target parameter; and
determining the size of the shelter unit according to the target parameter.

14. The method of claim 2, wherein determining the size of the shelter unit according to the simulation result and the phase stability indication comprises:
in a preset number of simulations, determining, in a case where an error between a simulation parameter corresponding to a current simulation result and the phase stability indication satisfies an error threshold, the simulation parameter corresponding to the current simulation result as a target parameter; and
determining the size of the shelter unit according to the target parameter.

15. The method of claim 3, wherein determining the size of the shelter unit according to the simulation result and the phase stability indication comprises:
in a preset number of simulations, determining, in a case where an error between a simulation parameter corresponding to a current simulation result and the phase stability indication satisfies an error threshold, the simulation parameter corresponding to the current simulation result as a target parameter; and
determining the size of the shelter unit according to the target parameter.

16. The method of claim 4, wherein determining the size of the shelter unit according to the simulation result and the phase stability indication comprises:
in a preset number of simulations, determining, in a case where an error between a simulation parameter corresponding to a current simulation result and the phase stability indication satisfies an error threshold, the simulation parameter corresponding to the current simulation result as a target parameter; and
determining the size of the shelter unit according to the target parameter.

17. The device of claim 9, wherein the phase stability indication comprises a first input pole being same as a second input pole;
wherein the first input pole is an input pole when a switch turns on a field-effect transistor, the second input pole is an input pole when the switch turns on the shelter unit, and the switch and the field-effect transistor are circuit units in the high frequency circuit model.

18. The device of claim 17, wherein the first input pole is win2, and win2 is determined by a first formula, wherein the first formula is:
$${w}_{in 2} = \frac{1}{{R}_{s} * [ {C}_{GS 2} + ( 1 + {g}_{m 2} * {R}_{D} ) * {C}_{GD 2} ]} ,$$
wherein Rs and RD are resistors in the high frequency circuit model, CGS2 and CGD2 are capacitors in the high frequency circuit model, and gm2 is a transconductance coefficient.

19. The device of claim 17, wherein the second input pole is win1, and win1 is determined by a second formula, wherein the second formula is:
$${w}_{in 1} = \frac{1}{{R}_{s} * [ {C}_{GS 1} + {C}_{GD 1} ]} ,$$
wherein Rs is a resistor in the high frequency circuit model, and CGS1 and CGD1 are capacitors in the high frequency circuit model.

20. The device of claim 9, wherein determining the size of the shelter unit according to the simulation result and the phase stability indication comprises:
determining a simulation parameter which is the closest to the phase stability indication among simulation parameters corresponding to simulation results of a preset number of simulations;
taking the closest simulation parameter as a target parameter; and
determining the size of the shelter unit according to the target parameter.

21. The device of claim 9, wherein determining the size of the shelter unit according to the simulation result and the phase stability indication comprises:
in a preset number of simulations, determining, in a case where an error between a simulation parameter corresponding to a current simulation result and the phase stability indication satisfies an error threshold, the simulation parameter corresponding to the current simulation result as a target parameter; and
determining the size of the shelter unit according to the target parameter.
